(19) United States
(12) Patent Application Publication
(10) Pub. No.: US 2026/0371687 A1
(43) Pub. Date: Nov. 19, 2026

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventor: Yushi OZU, Tokyo (JP)

(73) Assignee: Mitsubishi Electric Corporation, Tokyo (JP)

(21) Appl. No.: 19/532,053

(22) Filed: Feb. 6, 2026

(30) Foreign Application Priority Data
May 13, 2025 (JP) 2025-080737

(51) Int. Cl. H10D 64/00; H10D 30/01; H10D 30/47

(52) U.S. Cl. CPC H10D 64/118; H10D 30/015; H10D 30/471

(57) ABSTRACT

According to the present disclosure, a semiconductor device includes a semiconductor substrate; a first electrode and a second electrode on the semiconductor substrate; a first insulating film on the first electrode and the second electrode; a first polyimide layer on the first insulating film; a second insulating film on the first polyimide layer; a first wiring on the second insulating film and electrically connected to the first electrode; a second wiring on the second insulating film and electrically connected to the second electrode; a third insulating film on the first wiring and the second wiring; and a second polyimide layer on the third insulating film, wherein an opening is formed between the first wiring and the second wiring, the opening penetrating the second insulating film and the third insulating film, and the first polyimide layer and the second polyimide layer are in contact with each other through the opening.

### BACKGROUND

### Field

The present disclosure relates to a semiconductor device and a method for manufacturing the semiconductor device.

### BACKGROUND

JP2017-45864 A discloses a semiconductor device in which a polyimide film is formed on an insulating film. In this semiconductor device, a first pad is covered with the insulating film. A first opening exposes a portion of a surface of the first pad from the insulating film. A second opening connected to the first opening is formed in the first polyimide film. A first wiring groove connected to the second opening is formed in the second polyimide film. A first wiring is formed in the first opening, the second opening, and the first wiring groove.

In recent years, with the advancement of the information society, demand for semiconductor devices for wireless communication applications has been increasing. In semiconductor devices for wireless communication applications, HEMTs (High Electron Mobility Transistors) mainly using gallium arsenide (GaAs), LDMOSs (Laterally Diffused Metal Oxide Semiconductors) using Si, and the like have been used. However, with recent demands for miniaturization and higher output power, the development of HEMTs using gallium nitride (GaN), which has a wide bandgap, excellent breakdown voltage characteristics, and can achieve high output power density, is progressing.

In the development of GaN-HEMTs, a multi-layer wiring structure is generally employed to integrate circuits and improve reliability by increasing allowable current density. The multi-layer wiring is a structure in which a plurality of metal layers are stacked on a transistor. In a multi-layer wiring, polyimide is generally used as an interlayer insulating film in order to ensure the thickness between wirings.

However, the adhesion between the metal and the polyimide is low. Therefore, it is necessary to provide an insulating film between the metal and the polyimide. However, when a bias is applied to the semiconductor device under high temperature and high humidity environment, moisture penetrates into the interface between the insulating film with low adhesion and the polyimide, and ion migration may occur between wirings with different electric potentials.

### SUMMARY

The present disclosure has been made to solve the above-mentioned problems, and aims to provide a semiconductor device capable of suppressing ion migration and a method for manufacturing the semiconductor device.

The features and advantages of the present disclosure may be summarized as follows.

According to an aspect of the first disclosure, a semiconductor device includes a semiconductor substrate; a first electrode provided on an upper surface of the semiconductor substrate; a second electrode provided on the upper surface of the semiconductor substrate; a first insulating film provided on the first electrode and the second electrode; a first polyimide layer provided on the first insulating film; a second insulating film provided on the first polyimide layer; a first wiring provided on the second insulating film and electrically connected to the first electrode through a first through hole penetrating the first insulating film, the first polyimide layer, and the second insulating film; a second wiring provided on the second insulating film and electrically connected to the second electrode through a second through hole penetrating the first insulating film, the first polyimide layer, and the second insulating film; a third insulating film provided on the first wiring and the second wiring; and a second polyimide layer provided on the third insulating film, wherein an opening is formed between the first wiring and the second wiring, the opening penetrating the second insulating film and the third insulating film, and the first polyimide layer and the second polyimide layer are in contact with each other through the opening.

According to an aspect of the second disclosure, a semiconductor device includes a semiconductor substrate; a first electrode provided on an upper surface of the semiconductor substrate; a second electrode provided on the upper surface of the semiconductor substrate; a first insulating film provided on the first electrode and the second electrode; a first polyimide layer provided on the first insulating film; a second insulating film provided on the first polyimide layer; a first wiring provided on the second insulating film and electrically connected to the first electrode through a first through hole penetrating the first insulating film, the first polyimide layer, and the second insulating film; a second wiring provided on the second insulating film and electrically connected to the second electrode through a second through hole penetrating the first insulating film, the first polyimide layer, and the second insulating film; a third insulating film provided on the first wiring, the second wiring, and the second insulating film; and a second polyimide layer provided on the third insulating film, wherein an upper surface of the first polyimide layer is roughened.

According to an aspect of the first disclosure, a method for manufacturing a semiconductor device includes forming a first electrode and a second electrode on an upper surface of a semiconductor substrate; laminating a first insulating film, a first polyimide layer, and a second insulating film in this order on the first electrode and the second electrode; forming a first wiring on the second insulating, the first wiring electrically connected to the first electrode via a first through hole penetrating the first insulating film, the first polyimide layer, and the second insulating film; forming a second wiring on the second insulating film, the second wiring electrically connected to the second electrode via a second through hole penetrating the first insulating film, the first polyimide layer, and the second insulating film; forming a third insulating film on the first wiring and the second wiring; forming an opening penetrating the second insulating film and the third insulating film between the first wiring and the second wiring; and forming a second polyimide layer on the third insulating film, wherein the first polyimide layer and the second polyimide layer are in contact with each other through the opening.

According to an aspect of the second disclosure, a method for manufacturing a semiconductor device includes forming a first electrode and a second electrode on an upper surface of a semiconductor substrate; laminating a first insulating film and a first polyimide layer in this order on the first electrode and the second electrode; roughening an upper surface of the first polyimide layer by O2 ashing; forming a second insulating film on the roughened first polyimide layer; forming a first wiring on the second insulating, the first wiring electrically connected to the first electrode via a first through hole penetrating the first insulating film, the first polyimide layer, and the second insulating film; forming a second wiring on the second insulating film, the second wiring electrically connected to the second electrode via a second through hole penetrating the first insulating film, the first polyimide layer, and the second insulating film; forming a third insulating film on the first wiring, the second wiring, and the second insulating film; and forming a second polyimide layer on the third insulating film.

Other and further objects, features and advantages of the disclosure will appear more fully from the following description.

### BRIEF DESCRIPTION OF DRAWINGS

FIG. 1 is a cross-sectional view of a semiconductor device according to Embodiment 1.

FIG. 2 and FIG. 3 are diagrams illustrating a method for manufacturing the semiconductor device according to Embodiment 1.

FIG. 4 is a flowchart illustrating a method for manufacturing the semiconductor device according to Embodiment 1.

FIG. 5 is a cross-sectional view of a semiconductor device according to a comparative example.

FIG. 6 is a cross-sectional view of a semiconductor device according to Embodiment 2.

FIG. 7 and FIG. 8 are diagrams illustrating a method for manufacturing the semiconductor device according to Embodiment 2.

FIG. 9 is a flowchart illustrating the method for manufacturing the semiconductor device according to Embodiment 2.

FIG. 10 is a cross-sectional view of a semiconductor device according to Embodiment 3.

FIG. 11 and FIG. 12 are diagrams illustrating a method for manufacturing the semiconductor device according to Embodiment 3.

### DESCRIPTION OF EMBODIMENTS

The semiconductor device and the method for manufacturing the semiconductor device according to each embodiment will be described with reference to the drawings. The same reference numerals are assigned to the same or corresponding components, and repeated description may be omitted.

### Embodiment 1

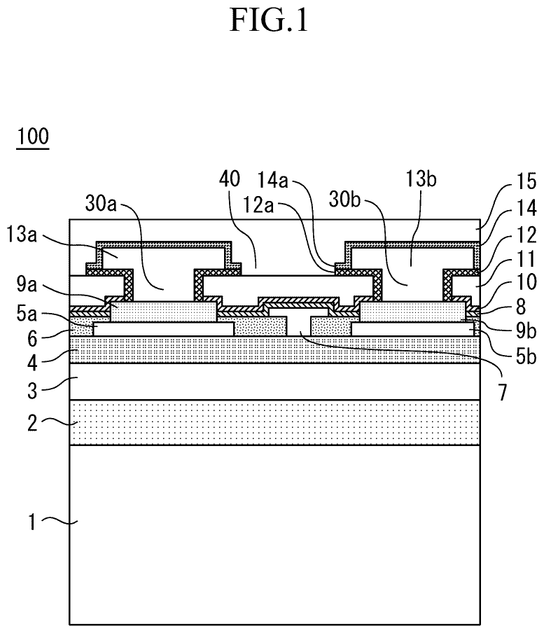

FIG. 1 is a cross-sectional view of a semiconductor device 100 according to Embodiment 1. The semiconductor device 100 is, for example, a GaN-HEMT. The semiconductor device 100 includes a semiconductor substrate 1. The semiconductor substrate 1 is formed of, for example, silicon carbide. A buffer layer 2, a channel layer 3, and a barrier layer 4 are stacked in this order on the semiconductor substrate 1. Hereinafter, the semiconductor substrate 1, the buffer layer 2, the channel layer 3, and the barrier layer 4 may be collectively referred to as a semiconductor substrate.

A drain electrode 5a serving as a first electrode, a source electrode 5b serving as a second electrode, and a gate electrode 7 are provided on an upper surface of the semiconductor substrate. In this way, a structure that operates as a transistor is built into the semiconductor device 100.

An insulating film 6 is provided on the upper surface of the semiconductor substrate, except for the drain electrode 5a, the source electrode 5b, and the gate electrode 7. An insulating film 8 is further provided on the insulating film 6. Through holes are formed in portions of the insulating films 6 and 8 above the drain electrode 5a and the source electrode 5b to expose the drain electrode 5a and the source electrode 5b. Metal wirings 9a and 9b are formed in the through holes. The metal wirings 9a and 9b are electrically connected to the drain electrode 5a and the source electrode 5b, respectively.

A first insulating film 10 is provided on the insulating film 8 and the metal wirings 9a, 9b. A first polyimide layer 11 is provided on the first insulating film 10. A second insulating film 12 is provided on the first polyimide layer 11. A first wiring 13a, which is a plated wiring, is provided on the second insulating film 12. The first wiring 13a is electrically connected to the drain electrode 5a through a first through hole 30a penetrating the first insulating film 10, the first polyimide layer 11, and the second insulating film 12. Furthermore, a second wiring 13b, which is a plated wiring, is provided on the second insulating film 12. The second wiring 13b is electrically connected to the source electrode 5b via a second through hole 30b penetrating the first insulating film 10, the first polyimide layer 11, and the second insulating film 12. The first wiring 13a and the second wiring 13b are formed on the metal wiring in order to increase allowable current density.

Note that the second insulating film 12 is also formed on the side surfaces of the first wiring 13a and the second wiring 13b within the first via hole 30a and the second via hole 30b. In other words, the inner walls of the first via hole 30a and the second via hole 30b are covered with the second insulating film 12.

A third insulating film 14 is provided on the first wiring 13a and the second wiring 13b. The third insulating film 14 covers the upper and side surfaces of the first wiring 13a and the second wiring 13b. A second polyimide layer 15 is provided as a surface protection film on the third insulating film 14. An opening 40 is formed between the first wiring 13a and the second wiring 13b, penetrating the second insulating film 12 and the third insulating film 14. The first polyimide layer 11 and the second polyimide layer 15 are in contact with each other through the opening 40.

The insulating film 6, the insulating film 8, the first insulating film 10, the second insulating film 12, and the third insulating film 14 are, for example, a SiN film, a SiO film, or a SiON film. These films have high electrical insulation properties and excellent chemical resistance and thermal stability. Also, the first polyimide layer 11 and the second polyimide layer 15 may be the same type of film.

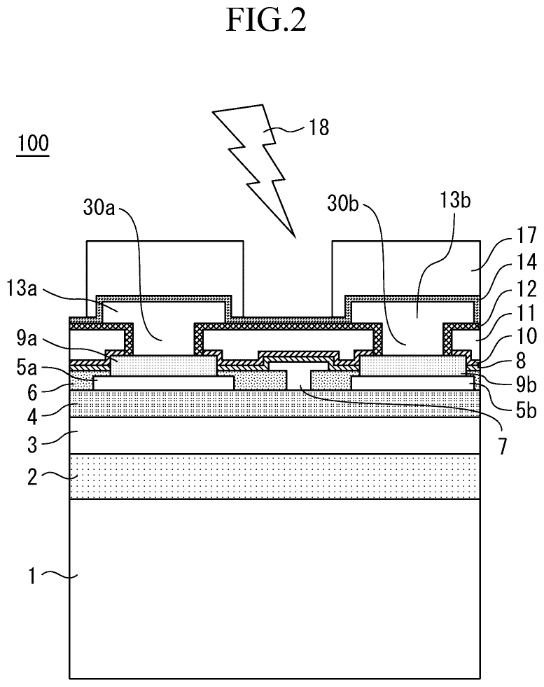

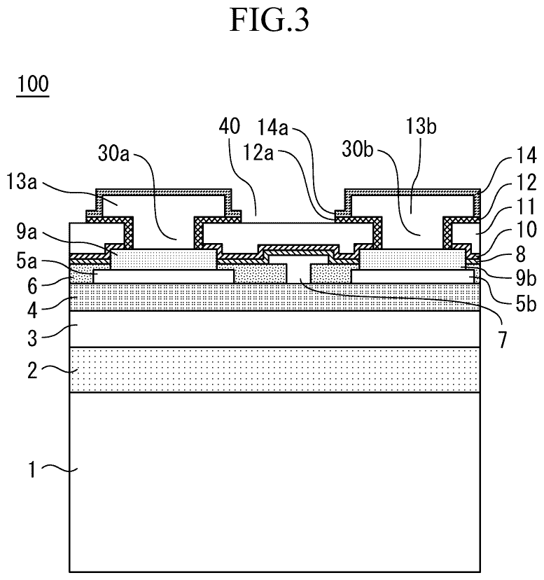

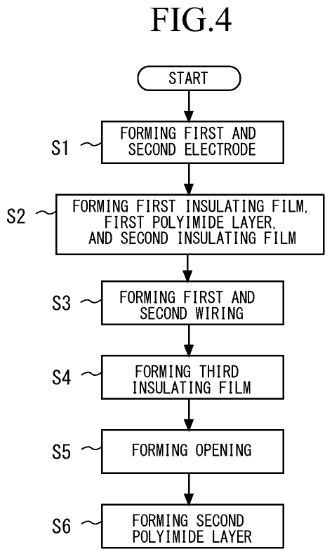

Next, a method for manufacturing the semiconductor device 100 will be described. FIG. 2 and FIG. 3 are diagrams illustrating a method for manufacturing the semiconductor device 100 according to Embodiment 1. FIG. 4 is a flowchart illustrating the method for manufacturing the semiconductor device 100 according to Embodiment 1. First, the buffer layer 2, the channel layer 3, and the barrier layer 4 are epitaxially grown in this order on the semiconductor substrate 1. GaN, AlGaN, or the like can be used as a material for the epitaxial growth layer. Next, the first electrode and the second electrode, that is, the drain electrode 5a and the source electrode 5b, are formed on the upper surface of the semiconductor substrate (step 1).

Next, the insulating films 6 and 8 are formed. Next, in order to contact the drain electrode 5a and the source electrode 5b with the metal wirings 9a, 9b, the insulating films 6, 8 are processed to form through holes exposing the drain electrode 5a and the source electrode 5b. Next, the metal wirings 9a, 9b are formed in the through holes.

Next, polyimide is formed as an interlayer insulating film between the metal wirings 9a, 9b and the first wiring 13a, the second wiring 13b. Here, the adhesion between the metal and the polyimide is low. Therefore, an insulating film is always formed on the metal wiring, on the polyimide, and on the plated wiring. That is, the first insulating film 10 is formed on the metal wirings 9a, 9b. Also, the second insulating film 12 is formed on the first polyimide layer 11. In other words, the first insulating film 10, the first polyimide layer 11, and the second insulating film 12 are laminated in this order on the first electrode and the second electrode (step 2). The second insulating film 12 may be formed after the formation of the first through hole 30a and the second through hole 30b.

Next, the first wiring 13a and the second wiring 13b are formed on the second insulating film 12 and inside the first through hole 30a and the second through hole 30b by plating (step 3). Next, the third insulating film 14 is formed on the first wiring 13a and the second wiring 13b (step 4).

Next, as shown in FIG. 2, only the portion between the first wiring 13a and the second wiring 13b of the second insulating film 12 and the third insulating film 14 is removed by dry etching 18 to form the opening 40 (step 5). At this time, the regions other than the portion to be etched are coated with a resist 17. As a result, the resist 17 functions as a protective film, and only the portion between the first wiring 13a and the second wiring 13b in the second insulating film 12 and the third insulating film 14 can be etched.

FIG. 3 shows a state in which the resist is removed after dry etching. As will be described later, a location where the opening 40 between the first wiring 13a and the second wiring 13b is formed is a region where ion migration has conventionally occurred. Next, the second polyimide layer 15 is formed on the third insulating film 14 (step 6). Thereby, as shown in FIG. 1, the first polyimide layer 11 and the second polyimide layer 15 are in contact with each other through the opening 40.

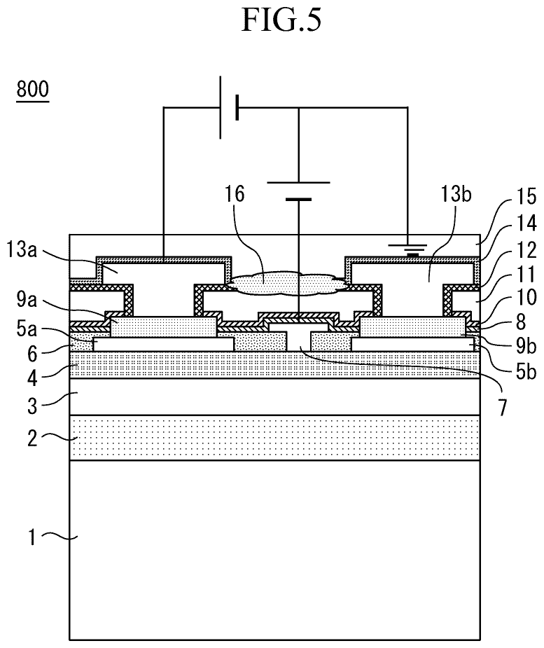

FIG. 5 is a cross-sectional view of a semiconductor device 800 according to a comparative example. In the semiconductor device 800 according to the comparative example, the opening 40 is not formed. In such a structure, the interface between the second polyimide layer 15 and the third insulating film 14, and the interface between the second insulating film 12 and the first polyimide layer 11, have low adhesion, and there is a risk of moisture intrusion. When a bias is applied to this semiconductor device 800 under a high-temperature and high-humidity environment as shown in FIG. 5, there is a risk that ion migration 16 may occur, particularly between the first wiring 13a and the second wiring 13b having different potentials.

In contrast, in the present embodiment, the first polyimide layer 11 and the second polyimide layer 15 are in contact with each other through the opening 40. Thereby, an interface can be formed between the first wiring 13a and the second wiring 13b with the same film type. That is, the interface between the first polyimide layer 11 and the second polyimide layer 15, which have good adhesion, can be formed in a portion where ion migration has conventionally occurred. Therefore, intrusion of moisture can be suppressed, and ion migration can be suppressed even when a bias is applied under a high-temperature and high-humidity environment.

Further, as shown in FIG. 1, the third insulating film 14 has a protruding portion 14a extending from the side surface of the first wiring 13a or the second wiring 13b along the upper surface of the first polyimide layer 11. Further, the second insulating film 12 has a protruding portion 12a protruding from below the first wiring 13a or the second wiring 13b into the region between the first wiring 13a and the second wiring 13b. The adhesion between metal and polyimide is weak. Therefore, it is preferable to leave the protruding portions 12a and 14a during dry etching so that the metal is not exposed from the insulating film. This can improve the adhesion of the second polyimide layer 15.

The materials and shapes of the respective layers are examples and are not limited to those described above. Further, since the first polyimide layer 11 and the second polyimide layer 15 are basically the same type of film, it can be said that they are the same layer. On the other hand, the surface of the first polyimide layer 11 has undergone various processes before the second polyimide layer 15 is formed. Therefore, the boundary between the two may be distinguishable if a detailed analysis is performed. Similarly, since the second insulating film 12 and the third insulating film 14 are basically the same type of film, it can be said that they are the same layer. If a detailed analysis is performed, the boundary between the two may be distinguishable.

The above-described modifications can be applied as appropriate to the semiconductor device and the method for manufacturing the semiconductor device according to the following embodiments. Since the semiconductor device and the method for manufacturing the semiconductor device according to the following embodiments have many points in common with Embodiment 1, the description will focus on the differences from Embodiment 1.

### Embodiment 2

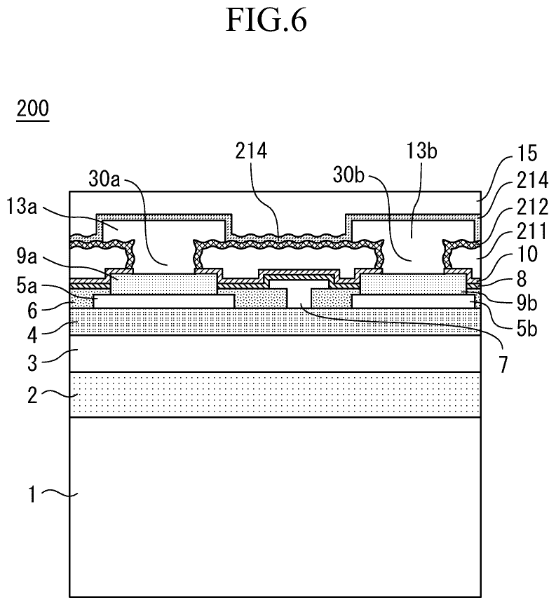

FIG. 6 is a cross-sectional view of a semiconductor device 200 according to Embodiment 2. In the present embodiment, the opening 40 is not formed. Therefore, the third insulating film 214 is provided on the second insulating film 212 in the region between the first wiring 13a and the second wiring 13b. Furthermore, the upper surface of the first polyimide layer 211 is roughened. Therefore, irregularities due to the influence of the shape of the upper surface of the first polyimide layer 211 appear on the surfaces of the second insulating film 212 and the third insulating film 214 provided on the first polyimide layer 211. Therefore, a surface of a portion of the third insulating film 214 provided on the second insulating film 212 is rougher than a surface of a portion provided on the first wiring 13a or the second wiring 13b. Other configurations are similar to the configuration of Embodiment 1.

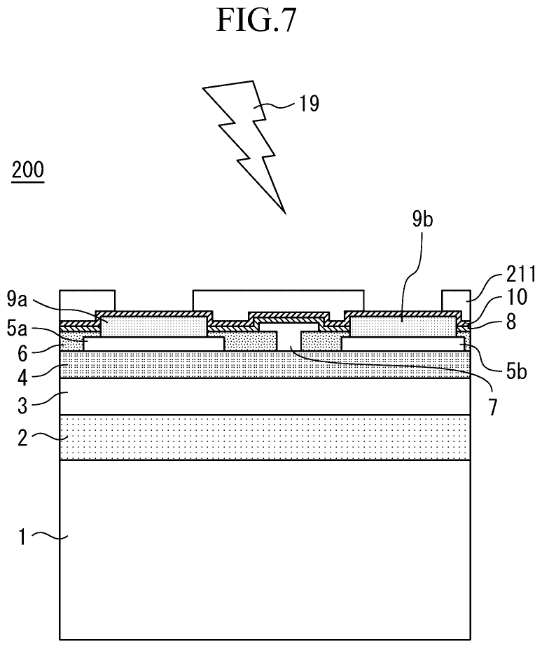

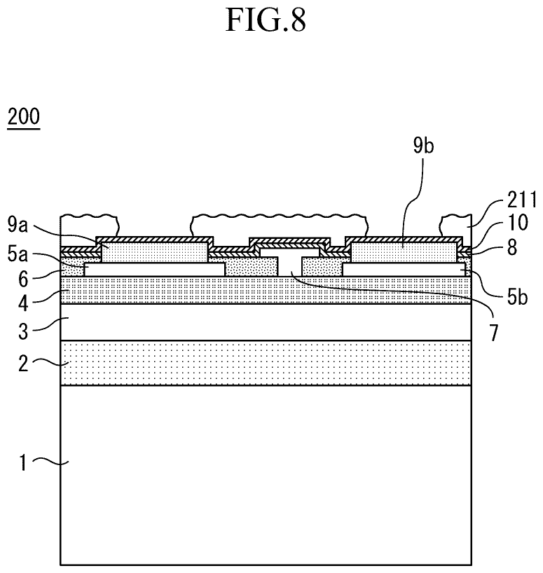

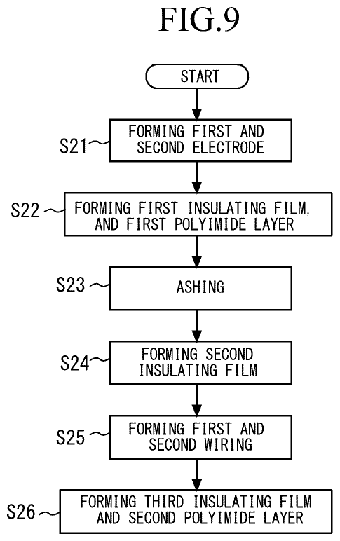

Next, a method for manufacturing the semiconductor device 200 according to the present embodiment will be described. FIG. 7 and FIG. 8 are diagrams illustrating a method for manufacturing the semiconductor device 200 according to Embodiment 2. FIG. 9 is a flowchart illustrating the method for manufacturing the semiconductor device 200 according to Embodiment 2. The steps up to forming the first and second electrodes (step 21), and forming the first insulating film 10 and the first polyimide layer 211 (step 22) are the same as the steps in Embodiment 1.

After forming the patterned first polyimide layer 211, O2 ashing 19 is performed as shown in FIG. 7 (step 23). According to O2 ashing, it is possible to remove the polyimide, which is an organic substance, by ashing it. At this time, the insulating film, which is an inorganic substance, is not removed. The O2 ashing is preferably performed under weak conditions to the extent that the upper surface of the first polyimide layer 211 is roughened. Thereby, as shown in FIG. 8, the first polyimide layer 211 with roughened upper and side surfaces is formed.

Next, the second insulating film 212 is formed on the roughened first polyimide layer 211 (step 24). Next, similarly to step 3, the first wiring 13a and the second wiring 13b are formed (step 25). Next, the third insulating film 214 is formed on the first wiring 13a, the second wiring 13b, and the second insulating film 212. Furthermore, the second polyimide layer 215 is formed on the third insulating film 214 (step 26).

By forming the second insulating film 212 and the third insulating film 214 on the roughened first polyimide layer 211, irregularities that inherit the shape of the surface of the roughened first polyimide layer 211 also appear on the surfaces of the second insulating film 212 and the third insulating film 214. This makes it possible to form irregularities at the interface between the first polyimide layer 211 and the second insulating film 212, and at the interface between the second polyimide layer 215 and the third insulating film 214.

Due to the anchoring effect of these irregularities, the contact area between the insulating film and the polyimide increases, thereby allowing the polyimide and the insulating film between the first wiring 13a and the second wiring 13b to adhere firmly. Therefore, moisture intrusion into the interface can be suppressed, and ion migration can also be suppressed even when a bias is applied under a high-temperature and high-humidity environment.

### Embodiment 3

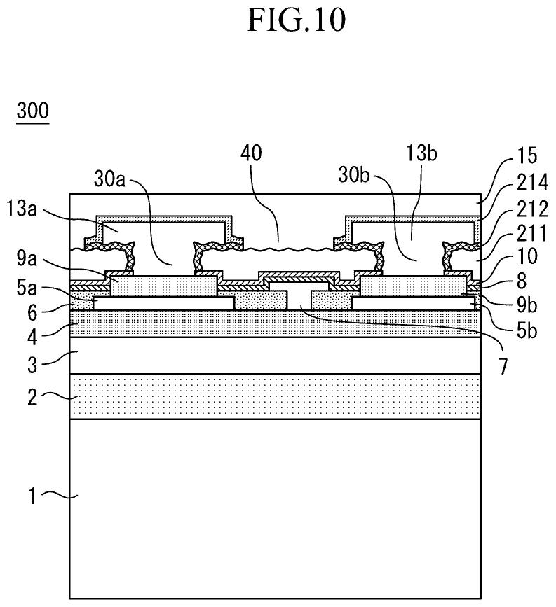

FIG. 10 is a cross-sectional view of a semiconductor device 300 according to Embodiment 3. In the semiconductor device 300, the first polyimide layer 211 and the second polyimide layer 15 are in contact with each other through the opening 40, as in Embodiment 1. The semiconductor device 300 differs from Embodiment 1 in that the upper surface of the first polyimide layer 211 is roughened. Other configurations are similar to those of Embodiment 1.

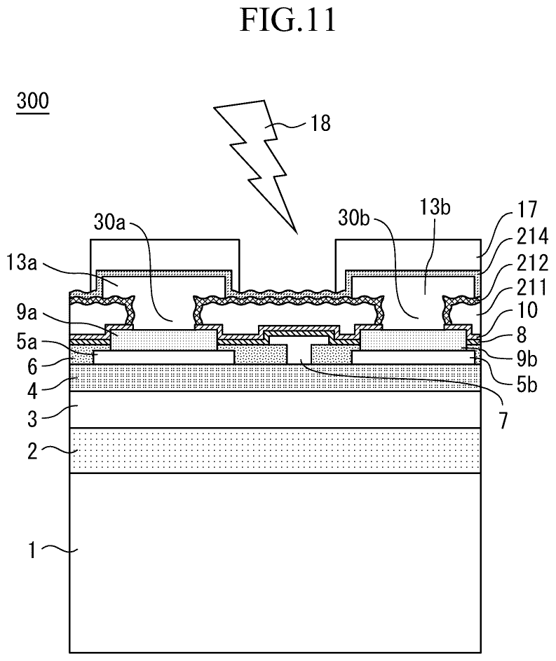

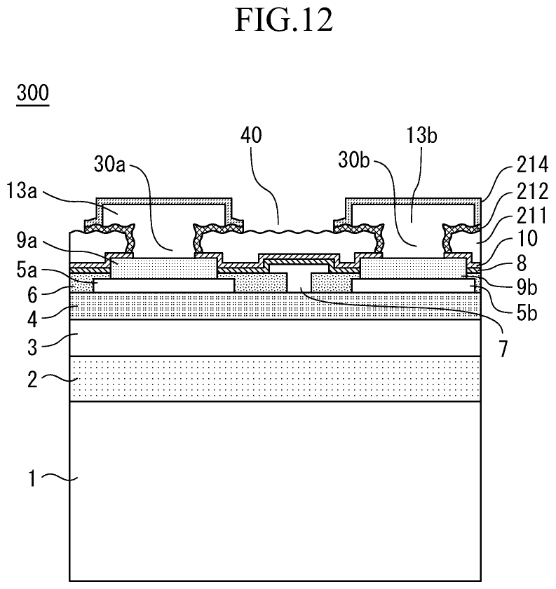

FIG. 11 and FIG. 12 are diagrams illustrating a method for manufacturing the semiconductor device 300 according to Embodiment 3. The method for manufacturing the semiconductor device 300 according to the present embodiment is the same as the manufacturing method according to Embodiment 2 up to the step of forming the third insulating film 214. Next, as shown in FIG. 11, the opening 40 is formed by dry etching 18, similarly to step 5 of Embodiment 1. FIG. 12 shows a state where the opening 40 is formed. The opening 40 exposes the first polyimide layer 11, which has a roughened surface, between the first wiring 13a and the second wiring 13. Next, as shown in FIG. 10, the second polyimide layer 15 is formed.

In the present embodiment, an interface between the first polyimide layer 11 and the second polyimide layer 15 of the same film type is formed between the first wiring 13a and the second wiring 13b where ion migration has conventionally occurred. Furthermore, a stronger interface structure can be formed by the anchoring effect of the roughened first polyimide layer 11 than in Embodiment 1. Therefore, intrusion of moisture into the interface can be suppressed, and ion migration can be suppressed even when a bias is applied under a high-temperature and high-humidity environment.

The technical features described in each embodiment may be combined and used as appropriate.

Hereinafter, various aspects of the present disclosure will be collectively described as appendixes.

### Appendix 1

A semiconductor device comprising:
a semiconductor substrate;
a first electrode provided on an upper surface of the semiconductor substrate;
a second electrode provided on the upper surface of the semiconductor substrate;
a first insulating film provided on the first electrode and the second electrode;
a first polyimide layer provided on the first insulating film;
a second insulating film provided on the first polyimide layer;
a first wiring provided on the second insulating film and electrically connected to the first electrode through a first through hole penetrating the first insulating film, the first polyimide layer, and the second insulating film;
a second wiring provided on the second insulating film and electrically connected to the second electrode through a second through hole penetrating the first insulating film, the first polyimide layer, and the second insulating film;
a third insulating film provided on the first wiring and the second wiring; and
a second polyimide layer provided on the third insulating film, wherein
an opening is formed between the first wiring and the second wiring, the opening penetrating the second insulating film and the third insulating film, and the first polyimide layer and the second polyimide layer are in contact with each other through the opening.

### Appendix 2

The semiconductor device according to appendix 1, wherein the first polyimide layer and the second polyimide layer are the same type of film.

### Appendix 3

The semiconductor device according to appendix 1 or 2, wherein
the third insulating film is:
covering upper surfaces and side surfaces of the first wiring and the second wiring, and
including a portion extending from the side surface of the first wiring or the second wiring along an upper surface of the first polyimide layer.

### Appendix 4

The semiconductor device according to any one of appendixes 1 to 3, wherein an upper surface of the first polyimide layer is roughened.

### Appendix 5

A semiconductor device comprising:
a semiconductor substrate;
a first electrode provided on an upper surface of the semiconductor substrate;
a second electrode provided on the upper surface of the semiconductor substrate;
a first insulating film provided on the first electrode and the second electrode;
a first polyimide layer provided on the first insulating film;
a second insulating film provided on the first polyimide layer;
a first wiring provided on the second insulating film and electrically connected to the first electrode through a first through hole penetrating the first insulating film, the first polyimide layer, and the second insulating film;
a second wiring provided on the second insulating film and electrically connected to the second electrode through a second through hole penetrating the first insulating film, the first polyimide layer, and the second insulating film;
a third insulating film provided on the first wiring, the second wiring, and the second insulating film; and
a second polyimide layer provided on the third insulating film, wherein
an upper surface of the first polyimide layer is roughened.

### Appendix 6

The semiconductor device according to appendix 5, wherein a surface of a portion of the third insulating film provided on the second insulating film is rougher than a surface of a portion of the third insulating film provided on the first wiring or the second wiring.

### Appendix 7

A method for manufacturing a semiconductor device, the method comprising:
forming a first electrode and a second electrode on an upper surface of a semiconductor substrate;
laminating a first insulating film, a first polyimide layer, and a second insulating film in this order on the first electrode and the second electrode;
forming a first wiring on the second insulating, the first wiring electrically connected to the first electrode via a first through hole penetrating the first insulating film, the first polyimide layer, and the second insulating film;
forming a second wiring on the second insulating film, the second wiring electrically connected to the second electrode via a second through hole penetrating the first insulating film, the first polyimide layer, and the second insulating film;
forming a third insulating film on the first wiring and the second wiring;
forming an opening penetrating the second insulating film and the third insulating film between the first wiring and the second wiring; and
forming a second polyimide layer on the third insulating film, wherein
the first polyimide layer and the second polyimide layer are in contact with each other through the opening.

### Appendix 8

A method for manufacturing a semiconductor device, the method comprising:
forming a first electrode and a second electrode on an upper surface of a semiconductor substrate;
laminating a first insulating film and a first polyimide layer in this order on the first electrode and the second electrode;
roughening an upper surface of the first polyimide layer by O2 ashing;
forming a second insulating film on the roughened first polyimide layer; forming a first wiring on the second insulating, the first wiring electrically connected to the first electrode via a first through hole penetrating the first insulating film, the first polyimide layer, and the second insulating film;
forming a second wiring on the second insulating film, the second wiring electrically connected to the second electrode via a second through hole penetrating the first insulating film, the first polyimide layer, and the second insulating film;
forming a third insulating film on the first wiring, the second wiring, and the second insulating film; and
forming a second polyimide layer on the third insulating film.

In the semiconductor device and the method for manufacturing the semiconductor device according to the first disclosure, the first polyimide layer and the second polyimide layer are in contact with each other through the opening. Therefore, the penetration of moisture can be suppressed, and ion migration can be suppressed.

In the semiconductor device and the method for manufacturing the semiconductor device according to the second disclosure, the upper surface of the first polyimide layer is roughened. Thereby, the adhesion between the polyimide and the insulating film can be improved. Therefore, the penetration of moisture can be suppressed, and ion migration can be suppressed.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2025-080737, filed on May 13, 2025 including specification, claims, drawings and summary, on which the Convention priority of the present application is based, are incorporated herein by reference in its entirety.

1. A semiconductor device comprising:
a semiconductor substrate;
a first electrode provided on an upper surface of the semiconductor substrate;
a second electrode provided on the upper surface of the semiconductor substrate;
a first insulating film provided on the first electrode and the second electrode;
a first polyimide layer provided on the first insulating film;
a second insulating film provided on the first polyimide layer;
a first wiring provided on the second insulating film and electrically connected to the first electrode through a first through hole penetrating the first insulating film, the first polyimide layer, and the second insulating film;
a second wiring provided on the second insulating film and electrically connected to the second electrode through a second through hole penetrating the first insulating film, the first polyimide layer, and the second insulating film;
a third insulating film provided on the first wiring and the second wiring; and
a second polyimide layer provided on the third insulating film, wherein
an opening is formed between the first wiring and the second wiring, the opening penetrating the second insulating film and the third insulating film, and the first polyimide layer and the second polyimide layer are in contact with each other through the opening.

2. The semiconductor device according to claim 1, wherein the first polyimide layer and the second polyimide layer are the same type of film.

3. The semiconductor device according to claim 1, wherein
the third insulating film is:
covering upper surfaces and side surfaces of the first wiring and the second wiring, and
including a portion extending from the side surface of the first wiring or the second wiring along an upper surface of the first polyimide layer.

4. The semiconductor device according to claim 1, wherein an upper surface of the first polyimide layer is roughened.

5. A semiconductor device comprising:
a semiconductor substrate;
a first electrode provided on an upper surface of the semiconductor substrate;
a second electrode provided on the upper surface of the semiconductor substrate;
a first insulating film provided on the first electrode and the second electrode;
a first polyimide layer provided on the first insulating film;
a second insulating film provided on the first polyimide layer;
a first wiring provided on the second insulating film and electrically connected to the first electrode through a first through hole penetrating the first insulating film, the first polyimide layer, and the second insulating film;
a second wiring provided on the second insulating film and electrically connected to the second electrode through a second through hole penetrating the first insulating film, the first polyimide layer, and the second insulating film;
a third insulating film provided on the first wiring, the second wiring, and the second insulating film; and
a second polyimide layer provided on the third insulating film, wherein
an upper surface of the first polyimide layer is roughened.

6. The semiconductor device according to claim 5, wherein a surface of a portion of the third insulating film provided on the second insulating film is rougher than a surface of a portion of the third insulating film provided on the first wiring or the second wiring.

7. A method for manufacturing a semiconductor device, the method comprising:
forming a first electrode and a second electrode on an upper surface of a semiconductor substrate;
laminating a first insulating film, a first polyimide layer, and a second insulating film in this order on the first electrode and the second electrode;
forming a first wiring on the second insulating, the first wiring electrically connected to the first electrode via a first through hole penetrating the first insulating film, the first polyimide layer, and the second insulating film;
forming a second wiring on the second insulating film, the second wiring electrically connected to the second electrode via a second through hole penetrating the first insulating film, the first polyimide layer, and the second insulating film;
forming a third insulating film on the first wiring and the second wiring;
forming an opening penetrating the second insulating film and the third insulating film between the first wiring and the second wiring; and
forming a second polyimide layer on the third insulating film, wherein
the first polyimide layer and the second polyimide layer are in contact with each other through the opening.

8. The semiconductor device according to claim 2, wherein
the third insulating film is:
covering upper surfaces and side surfaces of the first wiring and the second wiring, and
including a portion extending from the side surface of the first wiring or the second wiring along an upper surface of the first polyimide layer.

9. The semiconductor device according to claim 2, wherein an upper surface of the first polyimide layer is roughened.
